(19) United States
(12) Patent Application Publication
(10) Pub. No.: US 2010/0033939 A1
(43) Pub. Date: Feb. 11, 2010

(54) EARPIECE FIXING STRUCTURE AND ELECTRONIC DEVICE USING THE SAME

(75) Inventor: WEN-ZE LIU, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (Hong Kong) Limited, Kowloon (HK)

(21) Appl. No.: 12/471,552

(22) Filed: May 26, 2009

(30) Foreign Application Priority Data
Aug. 7, 2008 (CN) 200810303582.5

(51) Int. Cl. H05K 5/00

(52) U.S. Cl. 361/759

(57) ABSTRACT

An earpiece fixing structure is configured for fixing an earpiece module and a flexible printed circuit board in a fixing seat of an electronic device. The earpiece fixing structure comprises a cover and a plurality of latching portions bent from the cover. The cover covers the earpiece module and the flexible printed circuit board received in the fixing seat, and the latching portions latch to the fixing seat. Also disclosed is an electronic device using the earpiece fixing structure.

### BACKGROUND

1. Technical Field

The present disclosure relates to earpiece fixing structures and, particularly, to an earpiece fixing structure used in electronic devices.

2. Description of Related Art

With rapid development of information technology, electronic devices, such as cellular phones, personal digital assistants (PDA), and so on, are becoming increasingly more popular. Consequently, users may pay more attention to the suitability of the electronic devices for daily use. Thus, printed circuit boards of the electronic devices should stably connect to electronic components of the electronic device.

A typical electronic device often includes a main body having a receiving slot, a cover, a printed circuit board, and an earpiece module. The earpiece module and the printed circuit board are received in the receiving slot. The cover latches to the main body and presses the printed circuit board and the earpiece module in the receiving slot, thereby electronically connecting the printed circuit board to the earpiece module. However, if the cover becomes loose, the printed circuit board and the earpiece module will not be kept in good contact with each other, thereby affecting normal operation of the electronic device.

Therefore, there is room for improvement within the art.

### BRIEF DESCRIPTION OF THE DRAWINGS

Many aspects of the earpiece fixing structure and the electronic device using the earpiece fixing structure can be better understood with reference to the following drawings. The components in the drawings are not necessarily to scale, the emphasis instead being placed upon clearly illustrating the principles of the present earpiece fixing structure and the electronic device using the earpiece fixing structure. Moreover, in the drawings, like reference numerals designate corresponding parts throughout the several views:

FIG. 1 is a partial and exploded view of an electronic device in according with an exemplary embodiment.

FIG. 2 is similar to FIG. 1, but viewed from another angle.

FIG. 3 is a partial and assembled view of the electronic device in according with an exemplary embodiment.

### DETAILED DESCRIPTION OF THE EMBODIMENTS

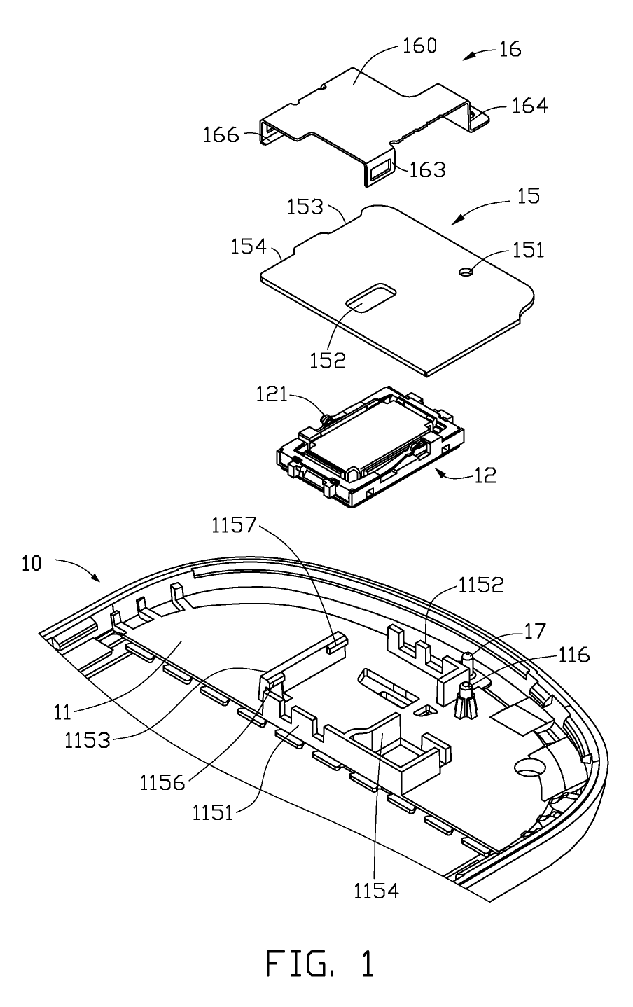

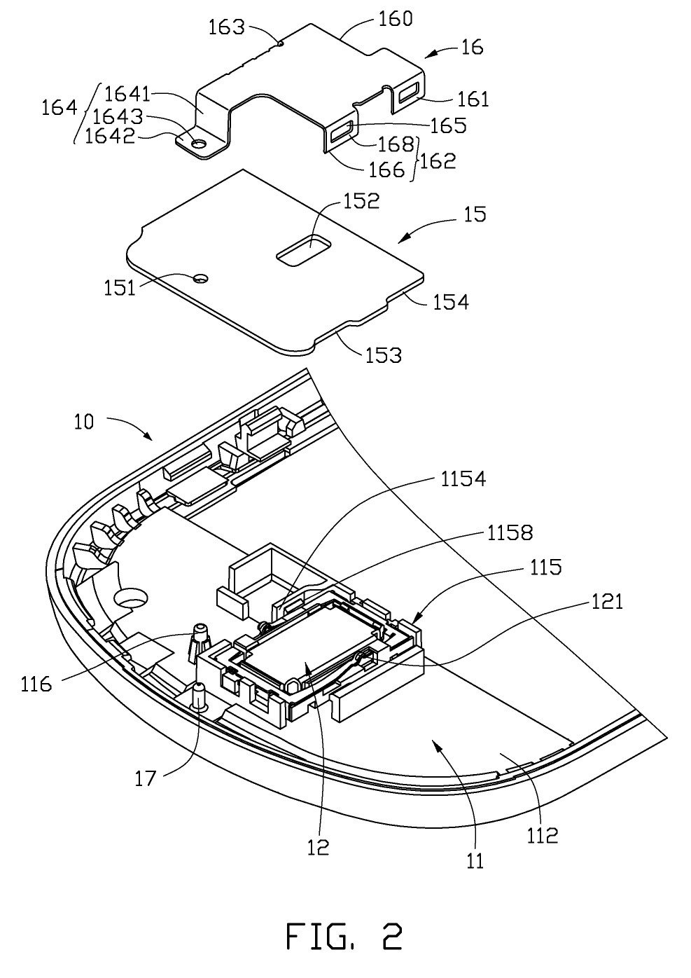

Referring to the drawings, FIG. 1 and FIG. 2 show an electronic device. The electronic device includes a main body 10, an earpiece module 12, a flexible printed circuit board (FPCB) 15, an earpiece fixing structure 16, and a fixing post 17. The earpiece fixing structure 16 is configured for fixing the earpiece module 12 and the flexible printed circuit board 15 in the main body 10.

The main body 10 is configured for receiving electronic components, and includes a receiving portion 11 having a bottom portion 112, a fixing seat 115, and a latching post 116. The fixing seat 115 is positioned in the bottom portion 112 adjacent to an end of the main body 10, and configured for receiving the earpiece module 12. The fixing seat 115 includes a first wall 1151, a second wall 1152 opposite to the first wall 1151, a third wall 1153, a fourth wall 1154 opposite to the third wall 1153, a first block 1156, a second block 1157 and a third block 1158. The first block 1156 and the second block 1157 extend from near opposite edges at a same side of the third wall 1153. The third block 1158 is positioned on the fourth wall 1154 and faces to the first block 1156 and the second block 1157. The latching post 116 is positioned on the bottom portion 112 adjacent to the fourth wall 1154.

The earpiece module 12 includes two spring clips 121 symmetrically positioned on a same side thereof. The spring clips 121 are configured for connecting to the flexible printed circuit board 15.

The flexible printed circuit board 15 defines a through hole 151, a mounting hole 152, a first gap 153, a second gap 154, and a plurality of contacting points (not shown) configured for connecting to the spring clips 121. The through hole 151 is matchable with the latching post 116. The mounting hole 152 is adjacent to the through hole 151. The first gap 153 and the second gap 154 are spaced from each other, and defined in a same edge of the flexible printed circuit board 15.

The earpiece fixing structure 16 includes a cover 160, and further includes a first latching portion 161, a second latching portion 162, a third latching portion 163, and a fixing portion 164 all similar in structure. Each of the latching portions 161, 162, 163 includes a main sheet 168 defining a latching hole 165 and a guiding sheet 166 bent from the main sheet 168. The latching hole 165 is matchable with any of the first block 1156, a second block 1157, and a third block 1158. The first latching portion 161 and the second latching portion 162 are bent from a same lateral side of the cover 160 and are spaced from each other. The third latching portion 163 is bent from another lateral side of the cover 160 opposite to the first latching portion 161. The fixing portion 164 is bent from a lateral side of the cover 160 adjacent to the lateral side forming the third latching portion 163. The fixing portion 164 is L-shaped, and includes a first sheet 1641 and a second sheet 1642 perpendicularly bent away from the first sheet 1641. The second sheet 1642 defines a locating hole 1643 therein.

The fixing post 17 is positioned on the bottom portion 112 adjacent to the second wall 1152. The fixing post 17 is engagable in the locating hole 1643.

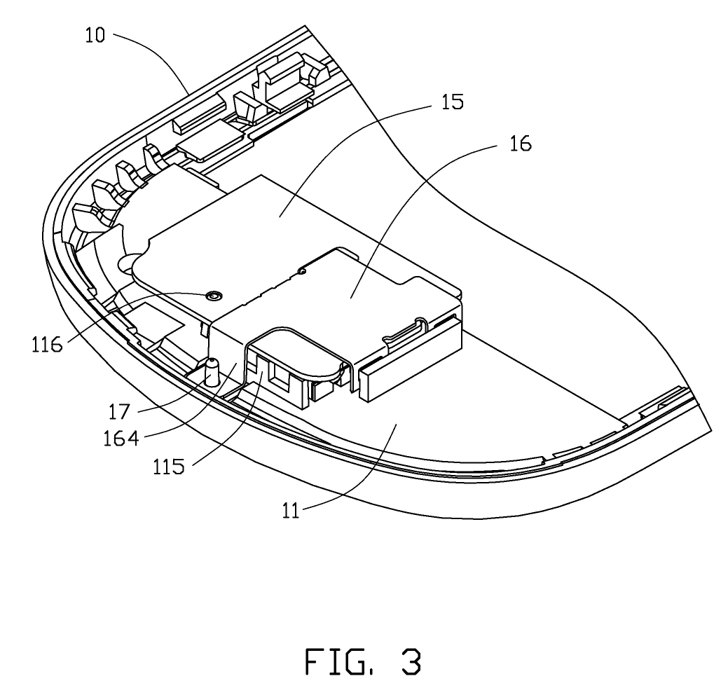

Referring to the drawing, FIG. 3, in assembly, the earpiece module 12 is placed into the fixing seat 115. The flexible printed circuit board 15 covers the earpiece module 12. Meanwhile, the contacting points electronically connect to the spring clips 121. The latching post 116 passes through the through hole 151. The mounting hole 152 corresponds to the third block 1158, thereby the third block 1158 being exposed out from the mounting hole 152. The cover 160 covers the flexible printed circuit board 15. The first block 1156 and the second block 1157 respectively pass the first gap 153 and the second gap 154, further engage into each latching hole 165 of the first latching portion 161 and the second latching portion 162. The third latching portion 163 passes through the mounting hole 152 and latches to the third block 1158. The fixing post 17 engages in the locating hole 1643.

The earpiece fixing structure 16 is latched to the fixing seat 115 and configured for fixing the earpiece module 12 and the flexible printed circuit board 15 on the main body 10 of the electronic device. The earpiece fixing structure 16 is configured to prevent the earpiece module 12 from being detached from the flexible printed circuit board 15. Furthermore, the earpiece fixing structure 16 is simple and takes up little space.

It is to be understood, however, that even through numerous characteristics and advantages have been set forth in the foregoing description of embodiments, together with details of the structure and function of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An earpiece fixing structure configured for fixing an earpiece module and a flexible printed circuit board in a fixing seat of an electronic device, comprising:
a cover;
a plurality of latching portions associated with the cover;
wherein the cover covers the earpiece module and the flexible printed circuit board is received in the fixing seat, and the latching portions latch to the fixing seat.

2. The earpiece fixing structure as claimed in claim 1, wherein the latching portions comprise a first latching portion, a second latching portion, and a third latching portion respectively defining a latching hole, the first latching portion and the second latching portion are bent from a same lateral side of the cover and are spaced from each other, the third latching portion is bent from a lateral side of the cover opposite to the first latching portion.

3. The earpiece fixing structure as claimed in claim 2, wherein the first latching portion, the second latching portion and the third latching portion respectively include a guiding sheet bent from an end thereof.

4. The earpiece fixing structure as claimed in claim 3, wherein the earpiece fixing structure further includes a fixing portion bent from a lateral side of the cover, the fixing portion includes a first sheet and a second sheet bent from the first sheet.

5. The earpiece fixing structure as claimed in claim 4, wherein the second sheet defines a locating hole configured for matching with a fixing post positioned on the electronic device.

6. An electronic device comprising:
a fixing seat;
an earpiece module received in the fixing seat;
a flexible printed circuit board covering the earpiece module;
an earpiece fixing structure; comprising:
a cover;
a plurality of latching portions associated with the cover;
wherein the cover covers the earpiece module and the flexible printed circuit board, and the latching portions latch to the fixing seat.

7. The electronic device as claimed in claim 6, wherein the latching portions comprise a first latching portion, a second latching portion, and a third latching portion respectively defining a latching hole, the first latching portion and the second latching portion are bent from a same lateral side of the cover and are spaced from each other, the third latching portion is bent from a lateral side of the cover opposite to the first latching portion.

8. The electronic device as claimed in claim 7, wherein the fixing seat includes a plurality of blocks corresponding to the latching portions, the blocks are engagable in the latching hole for fixing the earpiece fixing structure on the fixing seat.

9. The electronic device as claimed in claim 7, wherein the first latching portion, the second latching portion and the third latching portion respectively includes a guiding sheet bent from an end thereof.

10. The electronic device as claimed in claim 9, wherein the earpiece fixing structure further includes a fixing portion bent from a lateral side of the cover, the fixing portion includes a first sheet and a second sheet bent from the first sheet.

11. The electronic device as claimed in claim 10, wherein the second sheet defines a locating hole, the electronic device further includes a fixing post engaging in the locating hole.

12. The electronic device as claimed in claim 8, wherein the electronic device further includes a latching post, the flexible printed circuit board defines a through hole matching with the latching post.

13. The electronic device as claimed in claim 12, wherein the flexible printed circuit board further defines a mounting hole corresponding to the third latching portion, the third latching portion passes through the mounting hole and latches to the one of the blocks.

14. The electronic device as claimed in claim 12, wherein the flexible printed circuit board further defines a first gap and a second gap corresponding to the first latching portion and the second latching portion, the first latching portion and the second latching portion pass through the first gap and the second gap and latch to the blocks corresponding thereto.

15. The electronic device as claimed in claim 6, wherein the earpiece module includes spring clips configured for electronically connecting to the flexible printed circuit board.
